(19) United States
(12) Patent Application Publication
(10) Pub. No.: US 2026/0344032 A1
(43) Pub. Date: Oct. 29, 2026

(54) METHOD AND STRUCTURE FOR METAL GATE HAVING REDUCED THRESHOLD VOLTAGE SHIFT AND LOW EFFECTIVE CAPACITANCE

(71) Applicant: Taiwan Semiconductor Manufacturing Co., Ltd., Hsinchu (TW)

(72) Inventors: Yu-Lien Huang, Jhubei (TW); Yung-Cheng Lu, Hsinchu (TW)

(21) Appl. No.: 19/187,303

(22) Filed: Apr. 23, 2025

(51) Int. Cl. H10D 84/85; H10D 84/01

(52) U.S. Cl. CPC H10D 84/851; H10D 84/0172; H10D 84/0186

(57) ABSTRACT

In some embodiments, a device is provided that includes a gate cap on a metal gate conductor of a semiconductor device, and a dielectric layer over the gate cap. The device may further include an interlevel dielectric layer over the dielectric layer, and a contact through the interlevel dielectric layer and the dielectric layer, wherein the contact is in electrical communication with a source/drain region of the semiconductor device. The gate cap obstructs oxygen from processing for forming the interlevel dielectric layer from reaching the metal gate conductor.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 7A, 7B, 8A, 8B, 9A, 9B, 10A, 10B, 11A, 11B, 11C, 12A, 12B, 12C, 12D, 13A, 13B, 13C, 14A, 14B, 15A, 15B, 16A, 16B, 17A, 17B, 18, 19A, 19B, 20, 21, 22, 23, 24 and 25 are cross-sectional views of intermediate stages in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the methods and structures described herein can employ a contact etch stop layer (CESL) composed of a low-k dielectric material to reduce the effective capacitance (Ceff) of a field effect transistor structure, such as a nano-FET. A high dielectric constant material between conductive structures, such as a metal gate conductor and the contacts the source/drain region of a field effect transistor and/or metal overlying metal lines, can result in a high parasitic capacitance, which can negatively impact the switching speed of the device. By substituting a low-k dielectric material for the contact etch stop layer (CESL), the parasitic capacitance is reduced, e.g., the effective capacitance (Ceff) of the capacitor is reduced.

In some embodiments, the methods of the structures also provide for reducing the threshold voltage shift that can result from oxygen interacting with the metal gate conductors. Introducing oxygen into the metal gate conductor may create electric dipoles due to oxygen vacancies, which in turn alters the effective work function of the metal gate conductor material leading to shifts in the threshold voltage value. Higher oxygen content in the metal gate of a PMOS transistor generally leads to a higher threshold voltage, as it increases the effective work function, making it easier to turn the transistor on. Conversely, a higher oxygen content in an NMOS metal gate can lead to a lower threshold voltage.

High-k dielectrics when used as the material of the contact etch stop layer (CESL) that is atop the gate structure are generally dense materials that do not allow for oxygen to diffuse to the metal gate conductor. However, when substituting a low-k dielectric material for a dense high-k dielectric material, the low-k dielectric material may also have a lesser density, e.g., greater porosity, than the dense high-k dielectric layer. The high porosity allows for diffusion of oxygen through the contact etch stop layer to the metal gate conductor. In some embodiment, the methods and structures of the present disclosure position a high hermiticity material between the low-k dielectric material of the contact etch stop layer and the metal gate conductor. The high density, e.g., low porosity, of the high hermiticity material obstructs oxygen from reaching the metal gate conductor, substantially eliminating work function changes to the metal gate conductor that could result in a shift of the threshold voltage for the semiconductor devices.

Embodiments are described below in a particular context, a die comprising nano-FETs. Various embodiments may be applied, however, to dies comprising other types of transistors (e.g., fin field effect transistors (FinFETs), planar transistors, or the like) in lieu of or in combination with the nano-FETs.

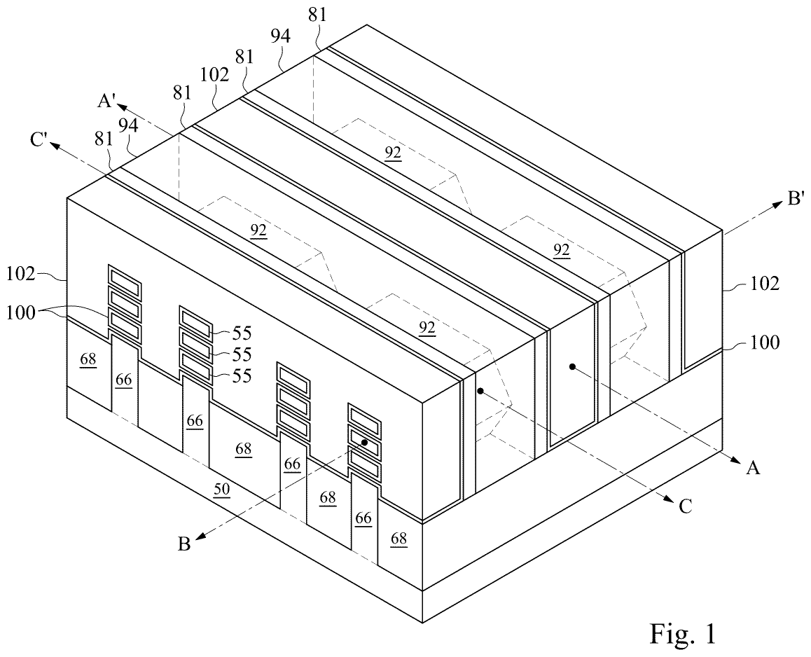

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 55 (e.g., nanosheets, nanowires, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 (also referred to as STI structures or STI regions) are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portions extending between the neighboring STI regions 68.

Gate dielectric layers 100 are over top surfaces of the fins 66 and along top surfaces, sidewalls, and bottom surfaces of the nanostructures 55. Gate electrodes 102 are over the gate dielectric layers 100, and gate spacers 81 are disposed along sidewalls of the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context. One or more dielectric layers (e.g., interlayer dielectric (ILD) 96) may be formed over the epitaxial source/drain regions 92 between the gate dielectric layers 100/gate electrodes 102.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

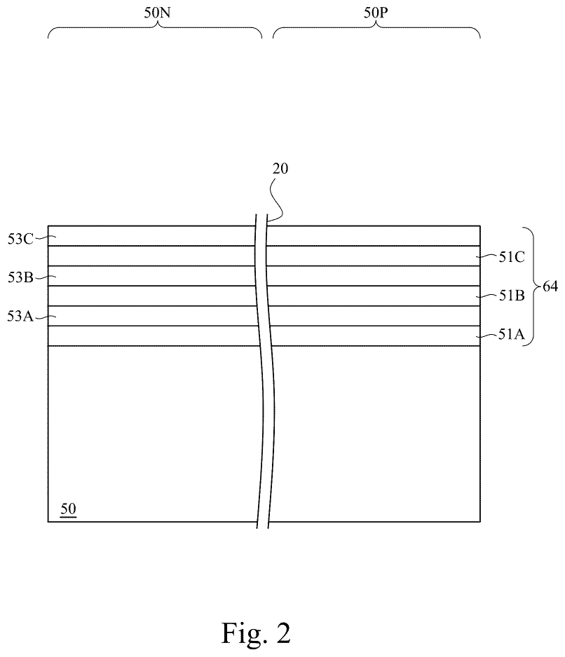

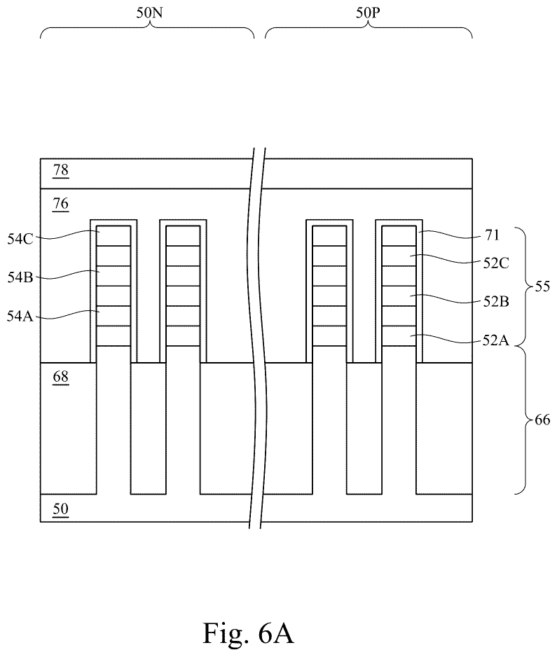

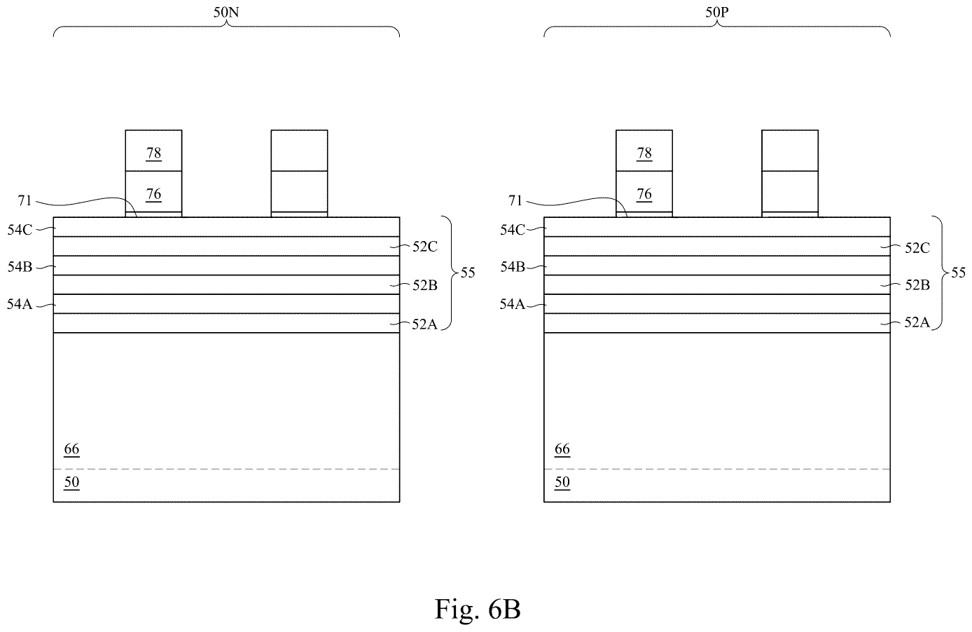

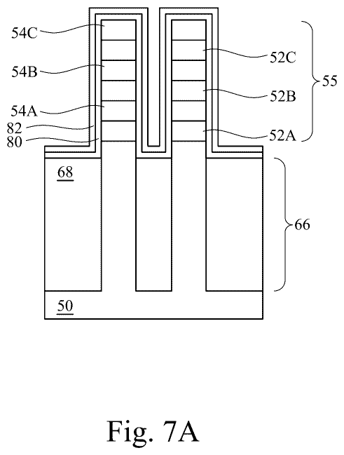

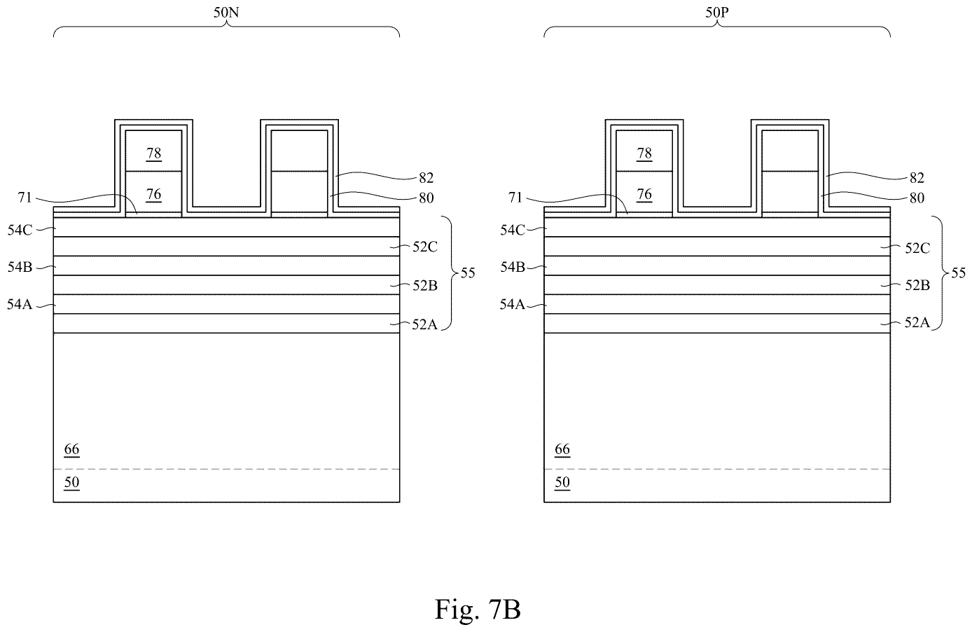

FIGS. 2 through 25 are cross-sectional views of intermediate stages in the manufacturing of nano-FETs, in accordance with some embodiments. FIGS. 2 through 5, 6A, 13A, 14A, 15A, 16A, 17A and 19A illustrate reference cross-section A-A′ illustrated in FIG. 1. FIGS. 6B, 7B, 8B, 9B, 10B, 11B, 11C, 12B, 12D, 13B, 14B, 15B, 16B, 17B, 18, 19B, 20, 21, 22, 23, 24 and 25 illustrate reference cross-section B-B′ illustrated in FIG. 1. FIGS. 7A, 8A, 9A, 10A, 11A, 12A, 12C, and 13C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs in the p-type region 50P. Also, the first semiconductor layers 51 will be removed and the second semiconductor layers 53 will be patterned to form channel regions of nano-FETs in the n-type region 50N. Nevertheless, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P.

In still other embodiments, the first semiconductor layers 51 may be removed and the second semiconductor layers 53 may be patterned to form channel regions of nano-FETS in both the n-type region 50N and the p-type region 50P. In other embodiments, the second semiconductor layers 53 may be removed and the first semiconductor layers 51 may be patterned to form channel regions of non-FETs in both the n-type region 50N and the p-type region 50P. In such embodiments, the channel regions in both the n-type region 50N and the p-type region 50P may have a same material composition (e.g., silicon, or another semiconductor material) and be formed simultaneously.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 50N, thereby allowing the second semiconductor layers 53 to be patterned to form channel regions of n-type nano-FETs. Similarly, the second semiconductor layers 53 of the second semiconductor material may be removed without significantly removing the first semiconductor layers 51 of the first semiconductor material in the p-type region 50P, thereby allowing the first semiconductor layers 51 to be patterned to form channel regions of p-type nano-FETs.

Further in FIG. 2, appropriate wells (not separately illustrated) may be formed in the first semiconductor layers 51, the second semiconductor layers 53, and/or the substrate 50. In embodiments with different well types, different implant steps for the n-type region 50N and the p-type region 50P may be achieved using a photoresist or other masks (not separately illustrated). For example, a photoresist may be formed over structures in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the structures in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴atoms/cm³ . After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the implantation process may be performed on the substrate 50 prior to forming the first semiconductor layers 51 and the second semiconductor layers 53. Subsequently, the grown materials of the first semiconductor layers 51 and/or the semiconductor layers 53 may be in situ doped during growth. Alternatively, the implantation process may be performed on one or more of the first semiconductor layers 51 and/or the second semiconductor layers 53.

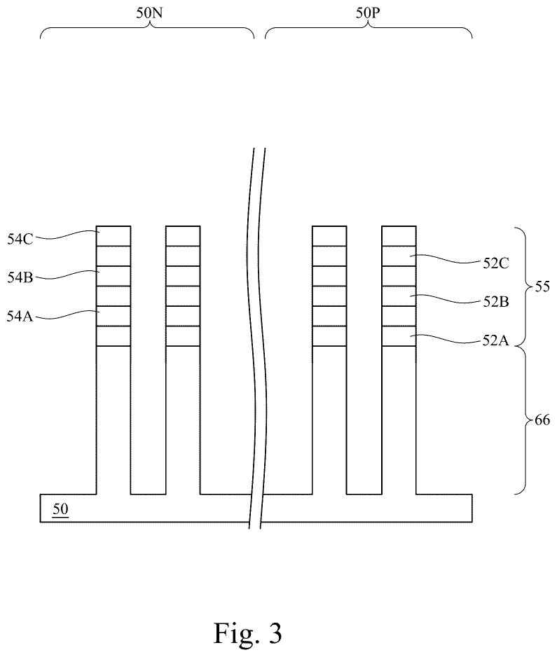

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

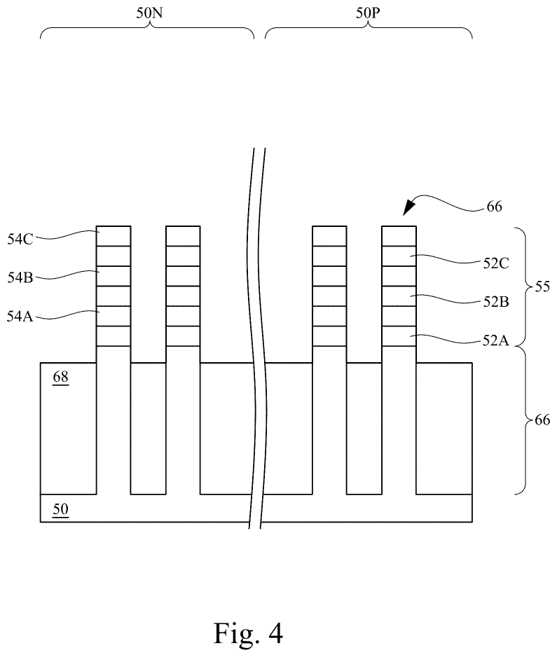

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, COR (Chemical Oxide Removal), a thermal HF/NF₃, a plasma NH₃/NF₃, or dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where, epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting nanostructures 52) and the second semiconductor layers 53 (and resulting nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

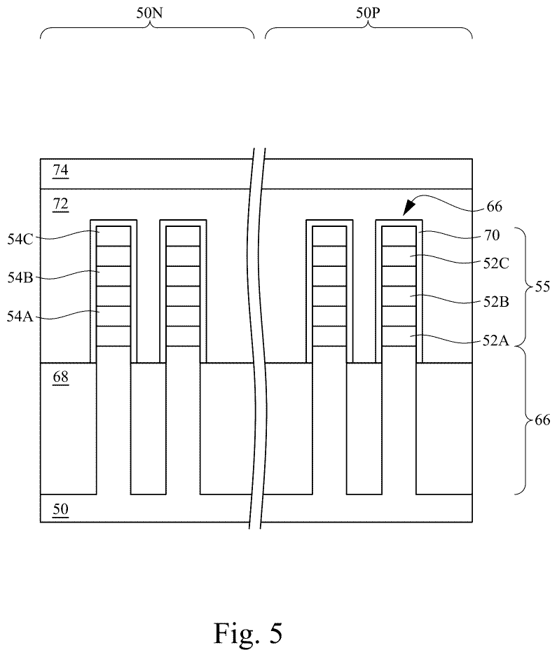

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 17B illustrate various additional steps in the manufacturing of embodiment devices. FIGS. 6A, 7A, 8A, 9A, 10A, 11A, 12A, 12C, 13A, 13C, 14A, 15A, and 17B illustrate features in either the regions 50N or the regions 50P. In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

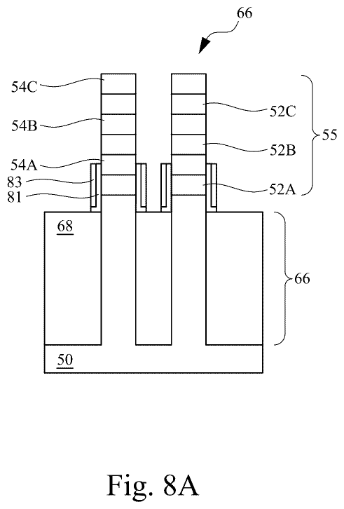

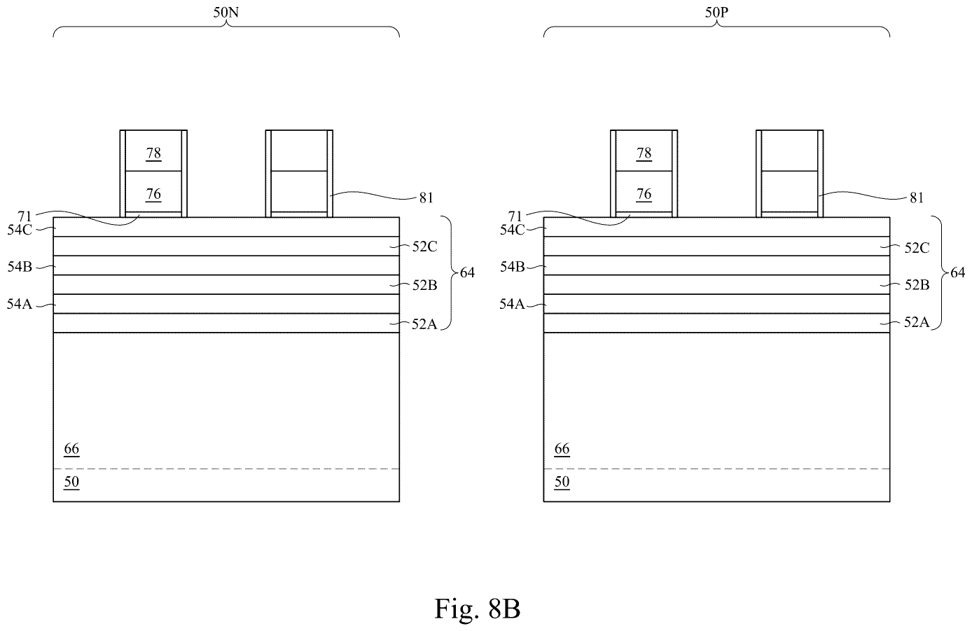

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

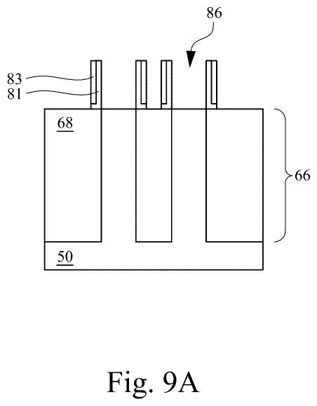

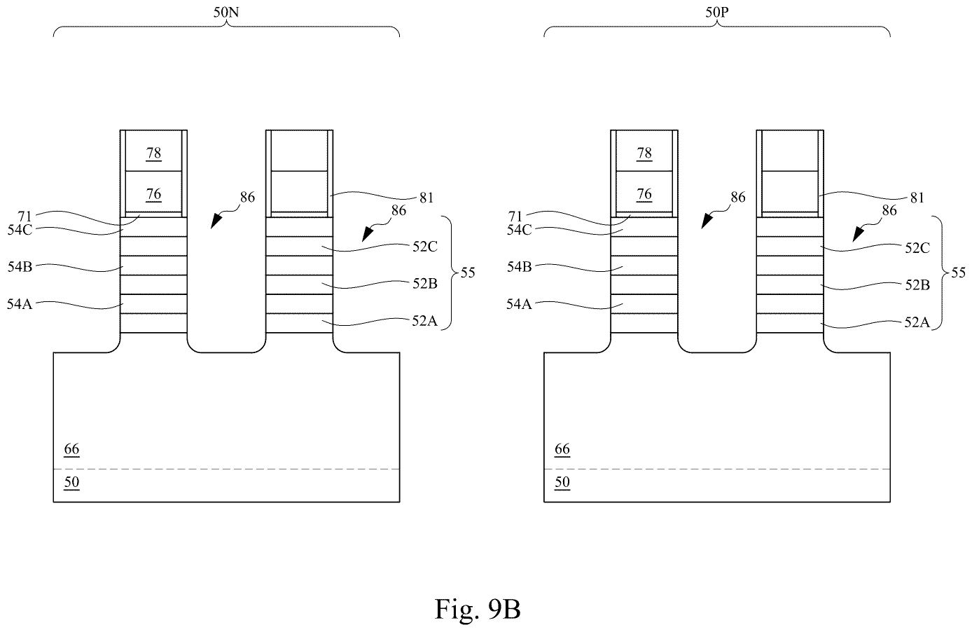

In FIGS. 9A and 9B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 9A, top surfaces of the STI regions 58 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

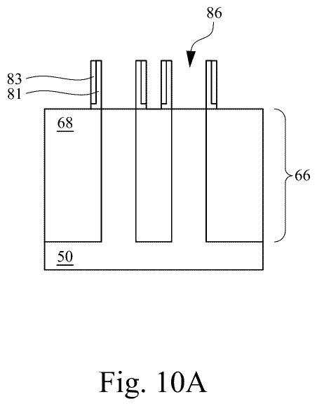

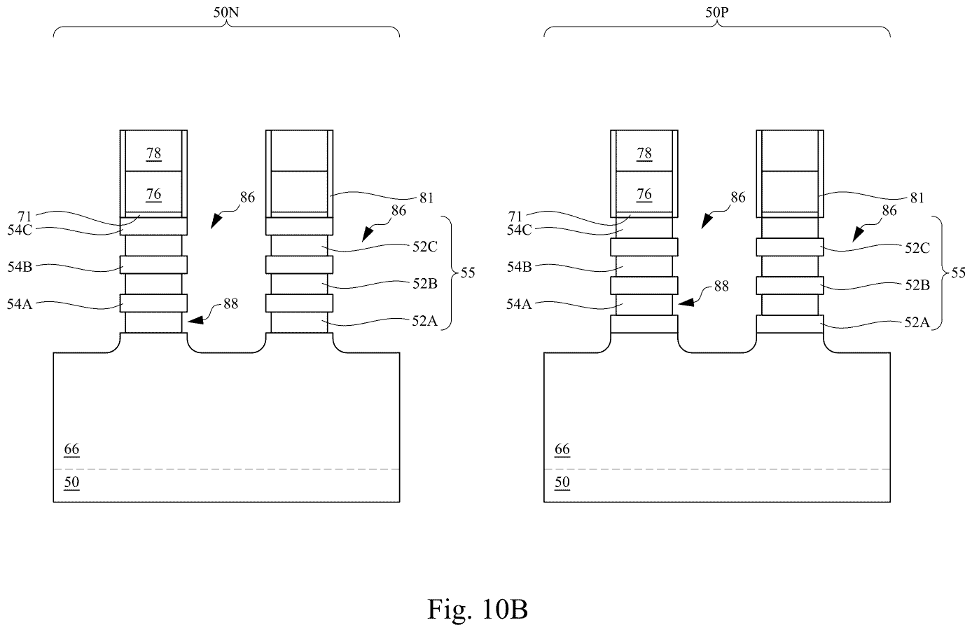

In FIGS. 10A and 10B, portions of sidewalls of the layers of the multi-layer stack 64 formed of the first semiconductor materials (e.g., the first nanostructures 52) exposed by the first recesses 86 are etched to form sidewall recesses 88 in the n-type region 50N, and portions of sidewalls of the layers of the multi-layer stack 56 formed of the second semiconductor materials (e.g., the second nanostructures 54) exposed by the first recesses 86 are etched to form sidewall recesses 88 in the p-type region 50P. Although sidewalls of the first nanostructures 52 and the second nanostructures 54 in sidewall recesses 88 are illustrated as being straight in FIG. 10B, the sidewalls may be concave or convex. The sidewalls may be etched using isotropic etching processes, such as wet etching or the like. The p-type region 50P may be protected using a mask (not shown) while etchants selective to the first semiconductor materials are used to etch the first nanostructures 52 such that the second nanostructures 54 and the substrate 50 remain relatively unetched as compared to the first nanostructures 52 in the n-type region 50N. Similarly, the n-type region 50N may be protected using a mask (not shown) while etchants selective to the second semiconductor materials are used to etch the second nanostructures 54 such that the first nanostructures 52 and the substrate 50 remain relatively unetched as compared to the second nanostructures 54 in the p-type region 50P. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N, and a wet or dry etch process with hydrogen fluoride, another fluorine-based etchant, or the like may be used to etch sidewalls of the second nanostructures 54 in the p-type region 50P.

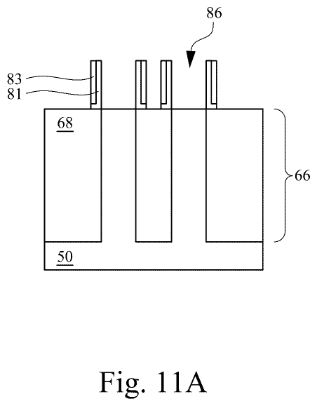

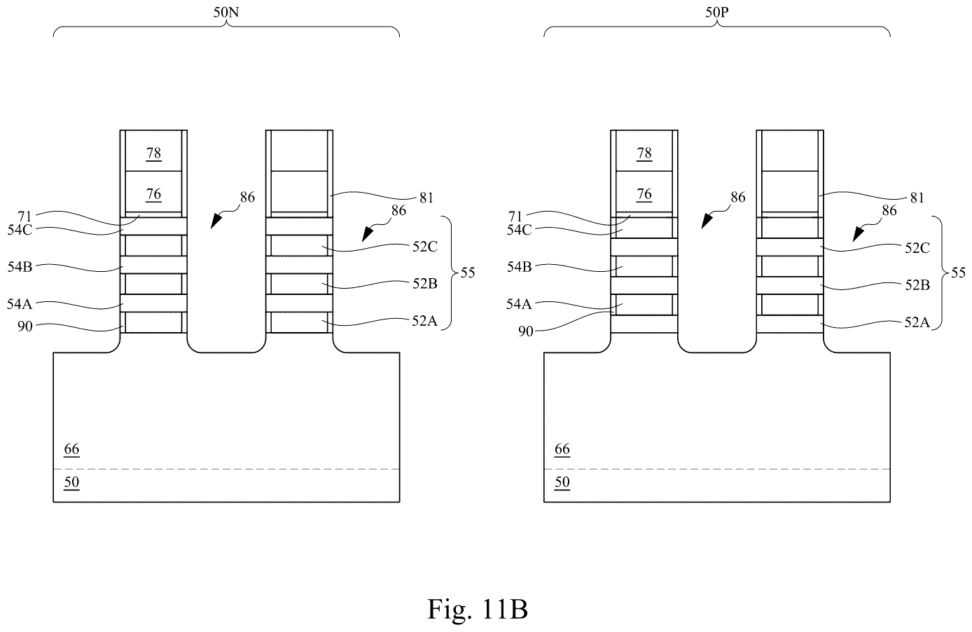

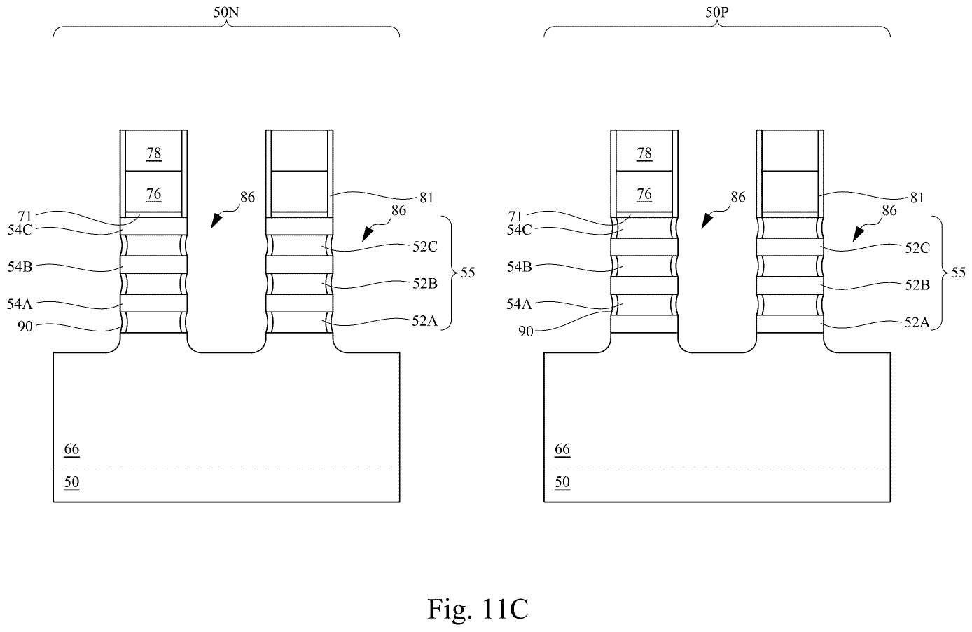

In FIGS. 11A-11C, first inner spacers 90 are formed in the sidewall recess 88. The first inner spacers 90 may be formed by depositing an inner spacer layer (not separately illustrated) over the structures illustrated in FIGS. 10A and 10B. The first inner spacers 90 act as isolation features between subsequently formed source/drain regions and a gate structure. As will be discussed in greater detail below, source/drain regions will be formed in the first recesses 86, while the first nanostructures 52 in the n-type region 50N and the second nanostructures 54 in the p-type region 50P will be replaced with corresponding gate structures.

The inner spacer layer may be deposited by a conformal deposition process, such as CVD, ALD, or the like. The inner spacer layer that provides the first inner spacers 90 may comprise a material such as silicon nitride or silicon oxynitride, although any suitable material, such as low-dielectric constant (low-k) materials having a k-value less than about 3.5, may be utilized. In some embodiments, the first inner spacers 90 may have a dielectric constant ranging from 3.0 to 10. In some embodiments, the first inner spacers 90 may have a density ranging from 2.6 g/cm³ to 3.2 g/cm³. In some embodiments, the first inner spacers 90 when composed of silicon nitride may have a dielectric constant ranging from 7.5 to 10. In some embodiments, the first inner spacers 90 when composed of silicon nitride may have a density of 3.17 g/cm³. In some embodiments, when the first inner spacers 90 are composed of silicon oxynitride, the dielectric constant of the first inner spacers 90 may range from 4.0 to 7.0, and the density may be equal to 2.83 g/cm³ .

The inner spacer layer may then be anisotropically etched to form the first inner spacers 90. Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52, respectively.

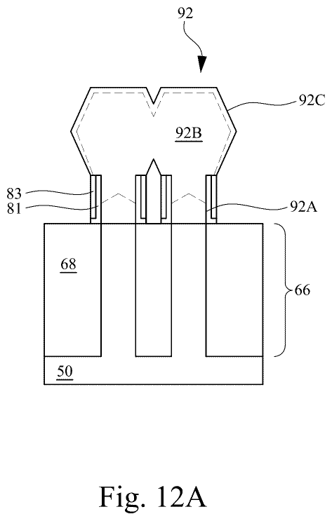

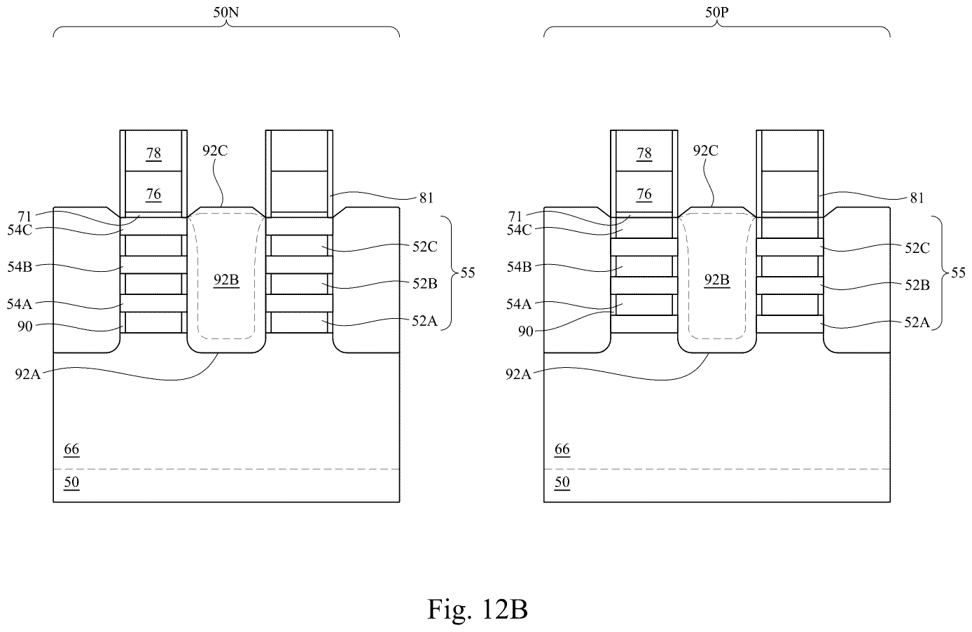

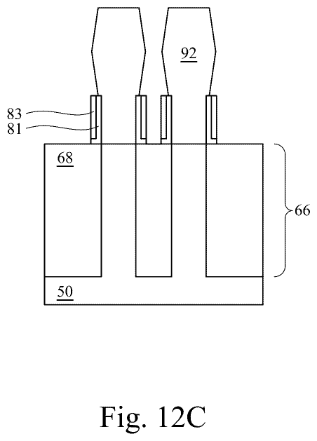

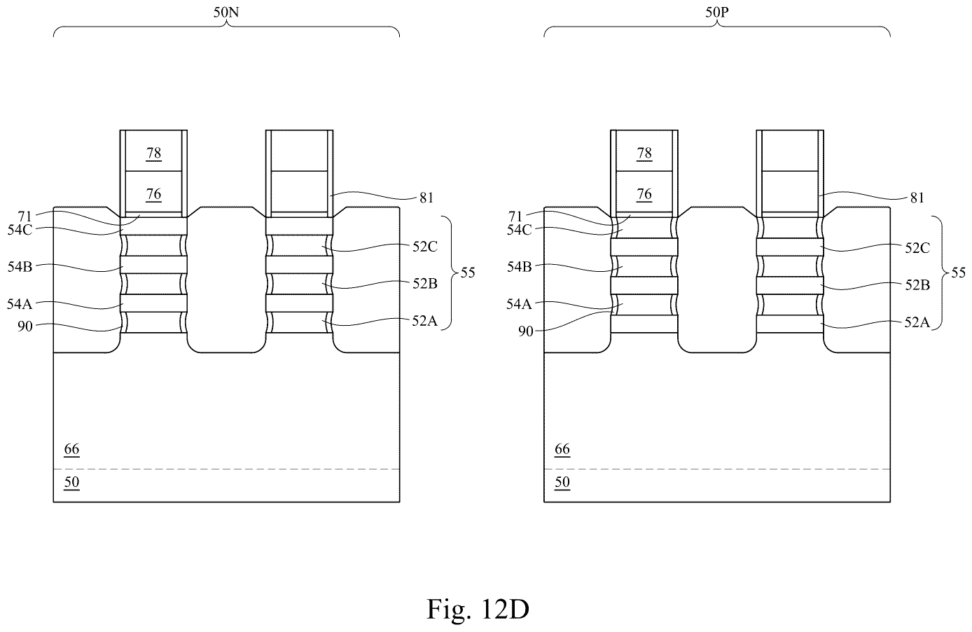

Moreover, although the outer sidewalls of the first inner spacers 90 are illustrated as being straight in FIG. 11B, the outer sidewalls of the first inner spacers 90 may be concave or convex. As an example, FIG. 11C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 12A-12C) by subsequent etching processes, such as etching processes used to form gate structures.

In FIGS. 12A-12C, epitaxial source/drain regions 92 are formed in the first recesses 86. In some embodiments, the source/drain regions 92 may exert stress on the second nanostructures 54 in the n-type region 50N and on the first nanostructures 52 in the p-type region 50P, thereby improving performance. As illustrated in FIG. 12B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12A. In other embodiments, adjacent epitaxial source/drain regions 92 remain separated after the epitaxy process is completed as illustrated by FIG. 12C. In the embodiments illustrated in FIGS. 12A and 12C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 58.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 12D illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52, respectively. As illustrated in FIG. 12D, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

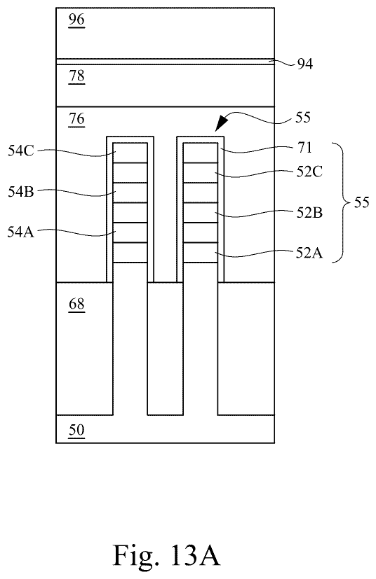

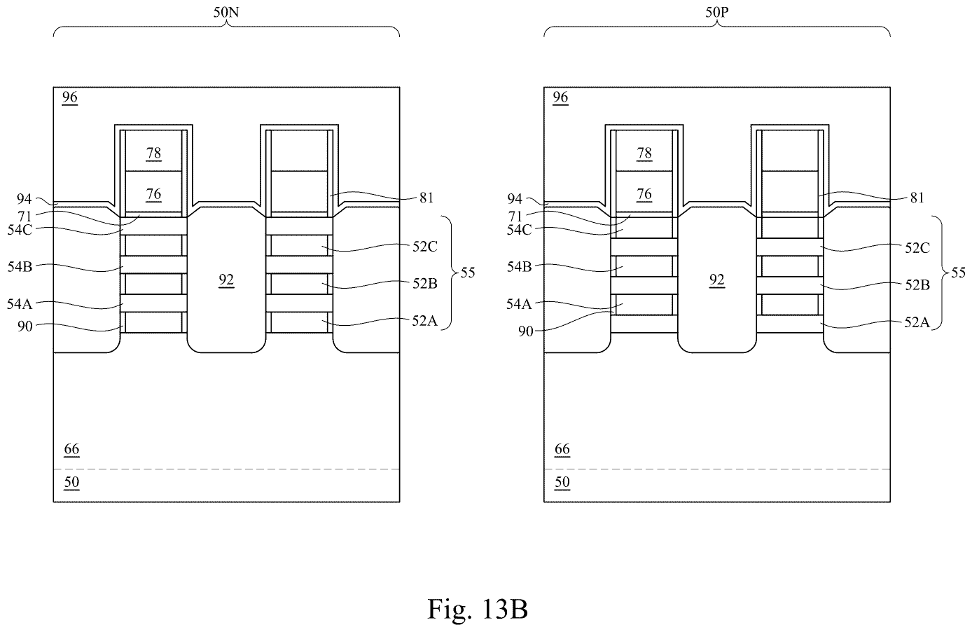

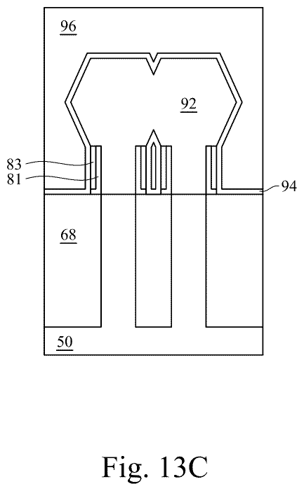

In FIGS. 13A-13C, a first interlayer dielectric (ILD) 96 is deposited over the structure illustrated in FIGS. 6A, 12B, and 12A (the processes of FIGS. 7A-12D do not alter the cross-section illustrated in FIG. 6A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. The first interlayer dielectric (ILD) 96 may have a dielectric constant ranging from 3.5 to 10. The density of the first interlayer dielectric (ILD) 96 may range from 2.0 g/cm³ to 2.5 g/cm³ . In some embodiments, when the first interlayer dielectric (ILD) 96 is phospho silicate glass (PSG) the dielectric constant may range from 3.5 to 4.5. In some embodiments, when the first interlayer dielectric layer (ILD) 96 is phospho silicate glass (PSG), the density of the first interlayer dielectric layer (ILD) 96 may be 2.23g/cm3. In some embodiments, when the first interlayer dielectric layer (ILD) 96 is composed of boron-doped phospho-silicate glass (BPSG) the dielectric constant may range from 3.7 to 10. In some embodiments, when the first interlayer dielectric layer (ILD) 96 is composed of boron-doped phospho-silicate glass (BPSG), the density of the first interlayer dielectric layer (ILD) 96 may be on the order of 2.23 g/cm³ . Other insulation materials formed by any acceptable process may be used.

In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96. In some embodiments, the contact etch stop layer (CESL) 94 may have a dielectric constant ranging from 3.0 to 10. In some embodiments, the contact etch stop layer (CESL) 94 may have a density ranging from 2.6 g/cm³ to 3.2g/cm³ . In some embodiments, the contact etch stop layer (CESL) 94 when composed of silicon nitride may have a dielectric constant ranging from 7.5 to 10. In some embodiments, the contact etch stop layer (CESL) 94 when composed of silicon nitride may have a density of 3.17 g/cm³. In some embodiments, the contact etch stop layer (CESL) 94 when composed of silicon oxide may have a dielectric constant of 3.9, and may have a density of 2.65 g/cm³. In some embodiments, when the contact etch stop player (CESL) 94 is composed of silicon oxynitride the dielectric constant of the contact etch stop layer (CESL) 94 may range from 4.0 to 7.0, and the density may be equal to 2.83 g/cm³.

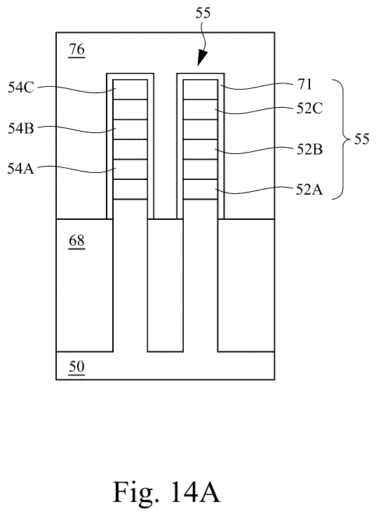

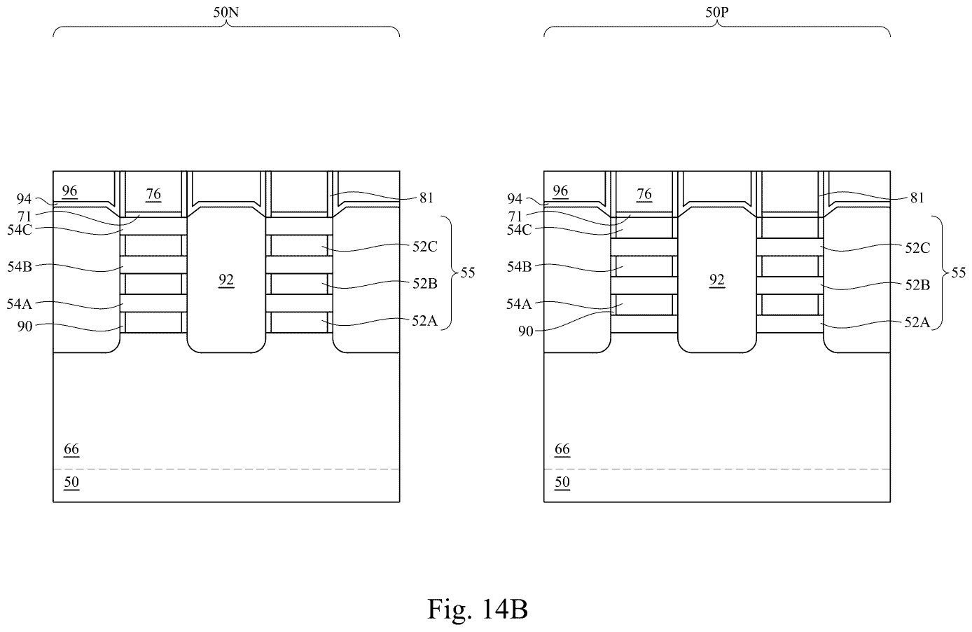

In FIGS. 14A-14C, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

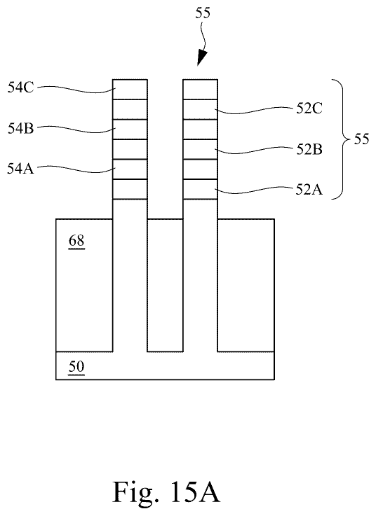

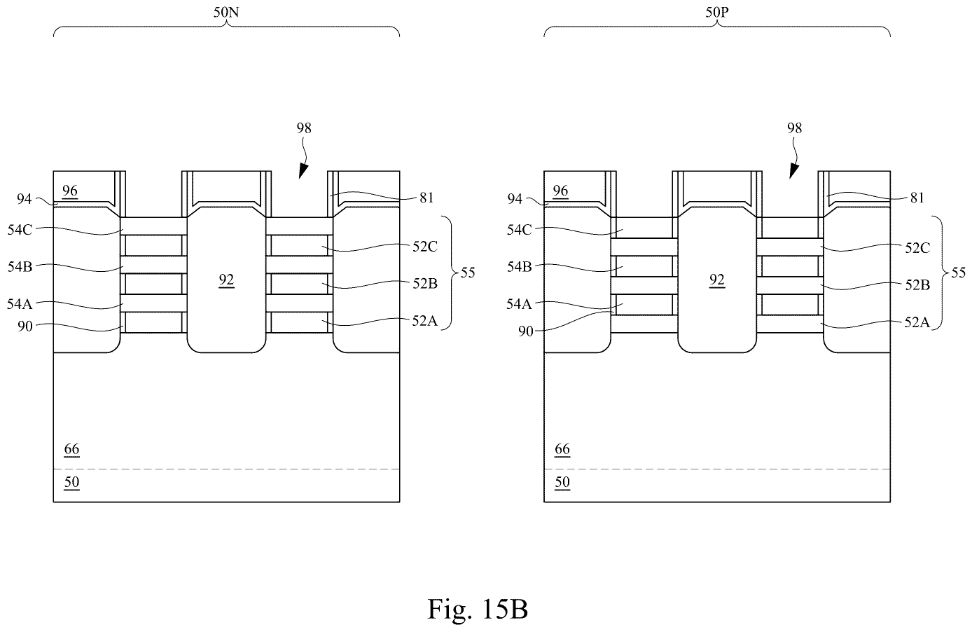

In FIGS. 15A and 15B, the dummy gates 76, and the masks 78 if present, are removed in one or more etching steps, so that second recesses 98 are formed. Portions of the dummy dielectric layers 60 in the second recesses 98 are also be removed. In some embodiments, the dummy gates 76 and the dummy dielectric layers 60 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 60 may then be removed after the removal of the dummy gates 76.

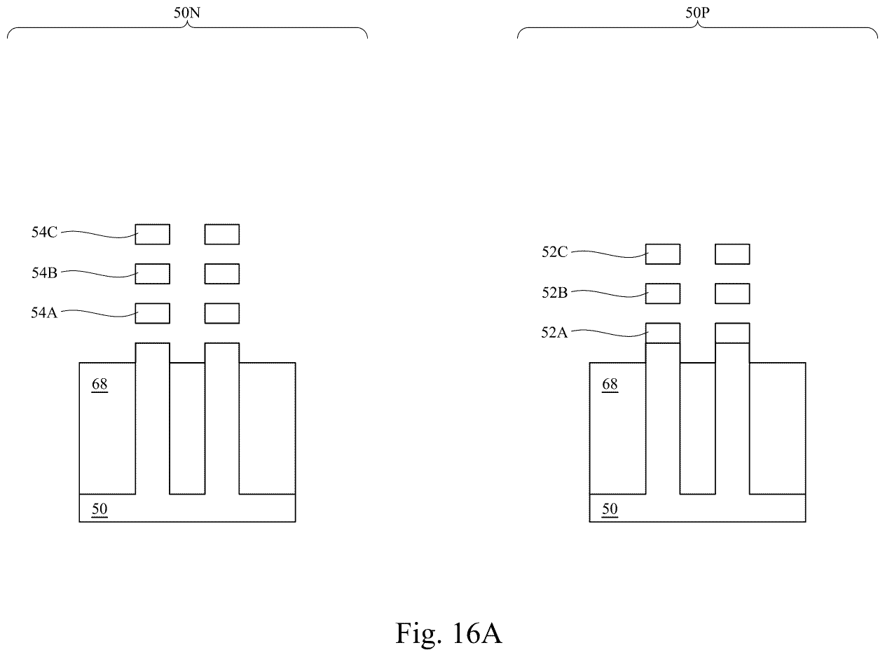

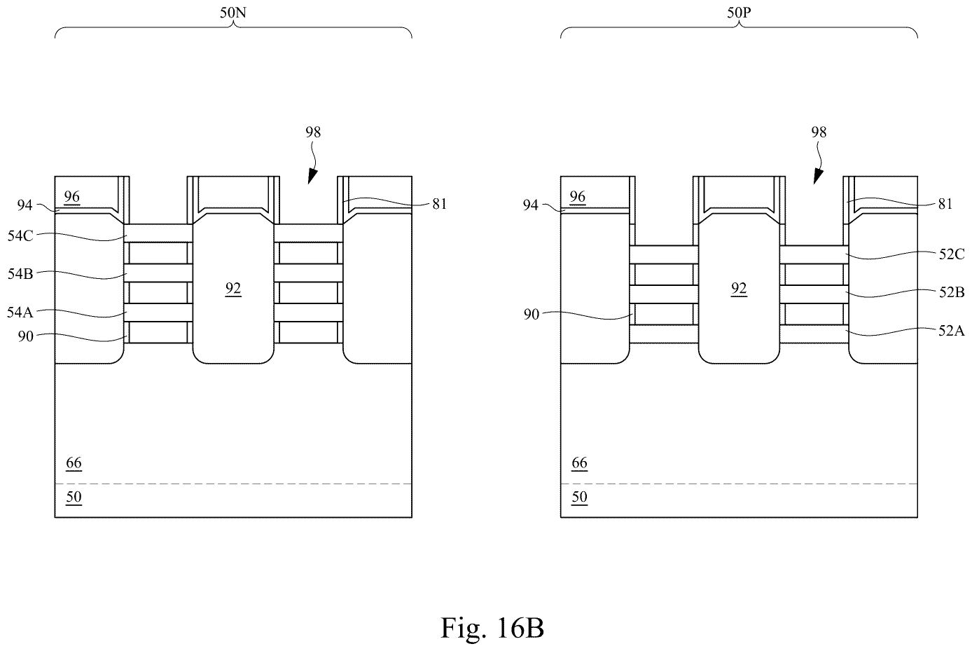

In FIGS. 16A and 16B, the first nanostructures 52 in the n-type region 50N and the second nanostructures 54 in the p-type region 50P are removed extending the second recesses 98. The first nanostructures 52 may be removed by forming a mask (not shown) over the p-type region 50P and performing an isotropic etching process such as wet etching or the like using etchants which are selective to the materials of the first nanostructures 52, while the second nanostructures 54, the substrate 50, the STI regions 58 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not shown) over the n-type region 50N and performing an isotropic etching process such as wet etching or the like using etchants which are selective to the materials of the second nanostructures 54, while the first nanostructures 52, the substrate 50, the STI regions 58 remain relatively unetched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

In other embodiments, the channel regions in the n-type region 50N and the p-type region 50P may be formed simultaneously, for example by removing the first nanostructures 52 in both the n-type region 50N and the p-type region 50P or by removing the second nanostructures 54 in both the n-type region 50N and the p-type region 50P. In such embodiments, channel regions of n-type nano-FETs and p-type nano-FETS may have a same material composition, such as silicon, silicon germanium, or the like.

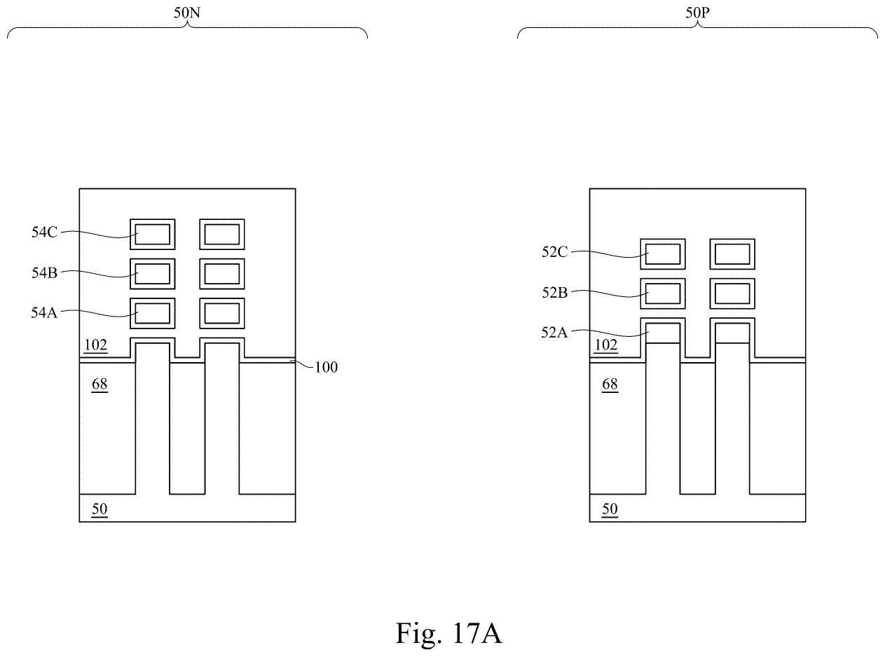

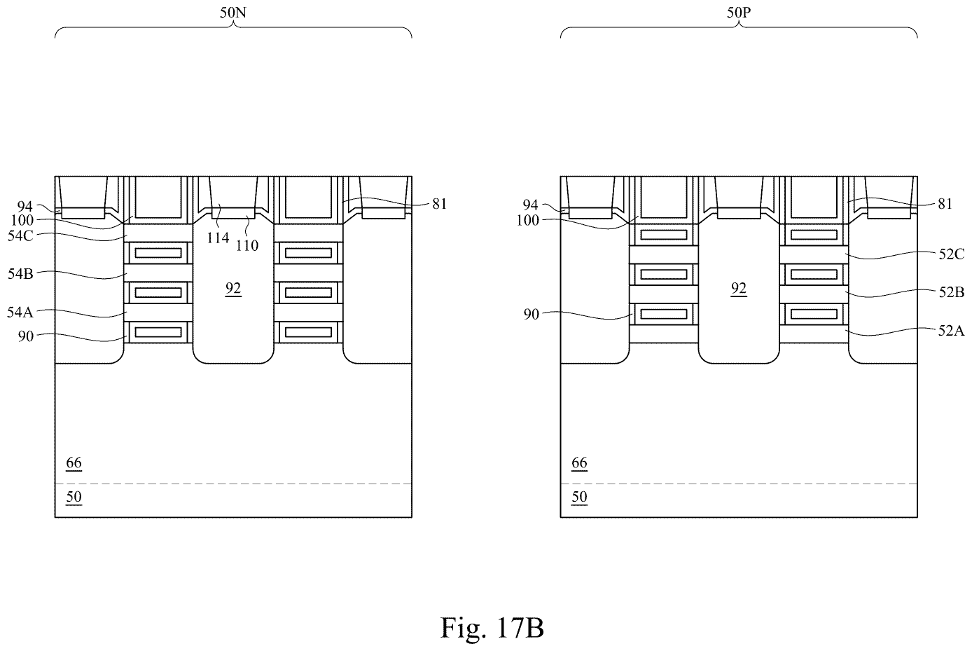

In FIGS. 17A and 17B, gate dielectric layers 100 and gate electrodes 102 are formed for replacement gates. The gate dielectric layers 100 are deposited conformally in the second recesses 98. In the n-type region 50N, the gate dielectric layers 100 may be formed on top surfaces and sidewalls of the substrate 50 and on top surfaces, sidewalls, and bottom surfaces of the second nanostructures 54, and in the p-type region 50P, the gate dielectric layers 100 may be formed on top surfaces and sidewalls of the substrate 50 and on top surfaces, sidewalls, and bottom surfaces of the first nanostructures 52. The gate dielectric layers 100 may also be deposited on top surfaces of the first ILD 96, the CESL 94, the first spacers 81, and the STI regions 58.

In accordance with some embodiments, the gate dielectric layers 100 comprise one or more dielectric layers, such as an oxide, a metal oxide, the like, or combinations thereof. For example, in some embodiments, the gate dielectric layers 100 may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIGS. 17A and 17B also depict forming first contacts 114 through the first ILD 96 to the epitaxial source/drain regions 92. In some embodiments, the first ILD 96, and the CESL 94 are etched to form third recesses exposing surfaces of the epitaxial source/drain regions 92. The third recesses may be formed by etching using an anisotropic etching process, such as RIE, NBE, or the like. In some embodiments, the third recesses may be etched through the first ILD 96 using a first etching process; and may then be etched through the CESL 94 using a second etching process. In some embodiments, the etching process may over-etch, and therefore, the third recesses extend into the epitaxial source/drain regions 92, and a bottom of the third recesses may be level with (e.g., at a same level, or having a same distance from the substrate), or lower than (e.g., closer to the substrate) the epitaxial source/drain regions 92 and/or the gate structure.

After the third recesses are formed, silicide regions 110 are formed onto the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

In FIGS. 17A and 17B, first contacts 114 (may also be referred to as contact plugs) are formed in the third recesses. The first contacts 114 may each comprise one or more layers, such as barrier layers, diffusion layers, and fill materials. For example, in some embodiments, the first contacts 114 each include a barrier layer and a conductive material, and is electrically coupled to the underlying conductive feature (e.g., silicide region 110 in the illustrated embodiment). The first contacts 114 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the first ILD 96.

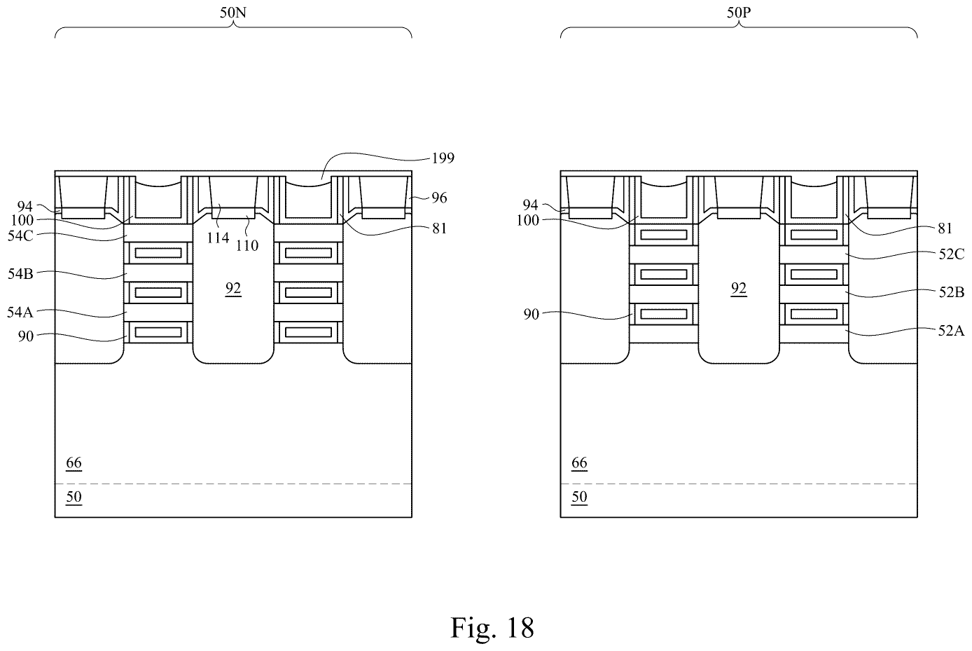

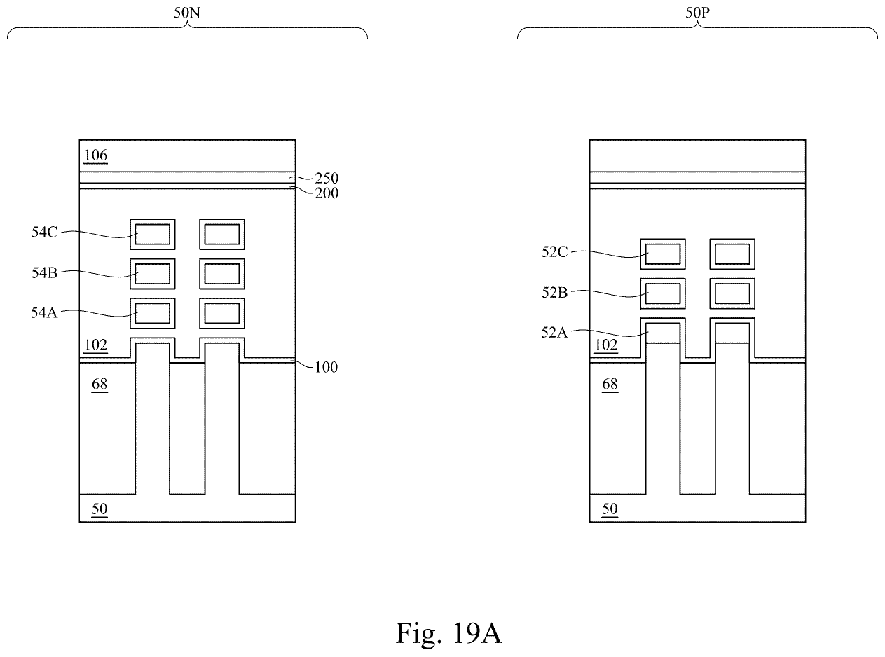

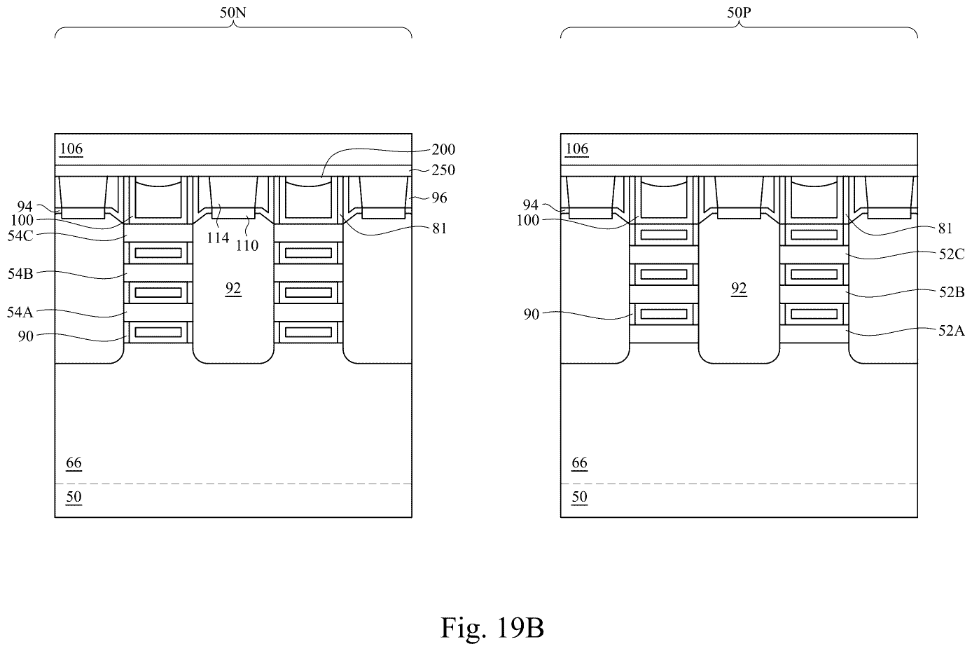

FIGS. 18-20 illustrate forming a high hermiticity dielectric cap 200 composed of a nitride containing material, such as silicon nitride, atop the gate electrode 102 (hereafter referred to as metal gate conductor 102), and then forming a middle contact etch stop layer (MCESL) 250 of a low-k dielectric material on the high hermiticity dielectric cap 200. A contact etch stop layer (CESL) composed of nitride containing material, e.g., silicon nitride, has a dielectric constant of approximately 7 or greater, whereas the low-k dielectric materials of the present disclosure may have a dielectric constant of 4.5 or less. A high dielectric constant material between conductive structures, such as a metal gate conductor 102 and the first contacts 114 (and subsequently formed second contacts 115, as depicted in FIG. 19) to the epitaxial source/drain regions 92 can result in a high parasitic capacitance, which can negatively impact the switching speed of the device. By employing a low-k dielectric material for the material of the middle contact etch stop layer (MCESL) 250, the parasitic capacitance is reduced, e.g., the effective capacitance (Ceff) of the capacitor is reduced. The lower effective capacitance (Ceff) that results from the low-k middle contact etch stop layer (MCESL) 250 can provide increased switching speed when compared to middle contact etch stop layers (MCESL) composed of high-k dielectric materials, such as silicon nitride. In one example, the middle contact etch stop layer (MCESL) 250 may be composed of silicon oxycarbide (SiOC).

The low-k middle contact etch stop layers (MCESL) 250 may have a high porosity. For example, a middle contact etch stop layer (MCESL) 250 of a low-k dielectric material, such as silicon oxycarbide, may have a density ranging from 2.0 to 2.4 g/cm³, which is less than the density of high-k dielectrics, such as silicon nitride, which can be 2.7 g/cm³ or greater. The increased porosity of the low-k middle contact etch stop layer (MCESL) 250 may allow for greater amounts of oxygen to diffuse through the middle contact etch stop layer (MCESL) 250 than a similar middle contact etch stop layer (MCESL) 250 composed of a higher density and higher dielectric constant material. Introducing oxygen into the metal gate conductor 102 that is underlying the middle contact etch stop layer (MCESL) 250 can create electric dipoles due to oxygen vacancies, which in turn alters the effective work function of the metal gate conductor material leading to shifts in the threshold voltage value. Higher oxygen content in the metal gate conductor 102 of a PMOS transistor generally leads to a higher threshold voltage, as it increases the effective work function, making it easier to turn the transistor on. Conversely, a higher oxygen content in the metal gate conductor 102 of an NMOS metal gate can lead to a lower threshold voltage.

In some embodiments, a high hermiticity material composed of a nitride, such as silicon nitride, provides a high hermiticity dielectric cap 200 (also referred to as hermetic cap) between the low-k dielectric material of the middle contact etch stop layer (MCESL) 250 and the metal gate conductor 102. The high density, e.g., low porosity, of the high hermiticity dielectric cap 200 obstructs oxygen from reaching the metal gate conductor 102, substantially eliminating work function changes to the metal gate conductor 102 that could result in a shift of the threshold voltage for the semiconductor devices. In some embodiments, the high hermiticity dielectric cap 200 may have a first density, and the low-k middle contact etch stop layer (MCESL) 250 may have a second density, in which the first density is greater than the second density.

FIG. 18 illustrates an embodiment of the gate structure (including the metal gate conductor 102) being recessed, so that a recess is formed directly over the gate structure and between opposing portions of first spacers 81. In some embodiments, the etch process for forming the recess removes an upper portion of the metal gate conductor 102 without removing the gate dielectric layer 100. In some embodiments, the gate dielectric has a U-shaped geometry when viewed from a side cross-section, and an upper surface of the metal gate conductor is recessed relative to the upper surface of the gate dielectric.

In some embodiments, a nitride containing material layer 199 which can comprise one or more layers of dielectric material, such as silicon nitride, silicon oxynitride, or the like, is deposited to fill the recess to provide the high hermiticity dielectric cap 200 (the high hermiticity dielectric cap 200 is depicted in FIGS. 19A and 19B). The nitride containing material layer 199 may be deposited using a chemical vapor deposition process, such as plasma enhanced chemical vapor deposition (PECVD). In one example, a nitride containing material layer 199 composed of plasma enhanced silicon nitride is blanket deposited not only filling the recess, but also extending atop the upper surfaces of the first ILD 96 and the first contacts 114. In some embodiments, the high hermicity dielectric cap 200 may be composed of silicon nitride, and may have a dielectric constant ranging from 6.3 to 7.5.

It is noted that silicon nitride is only one example of a nitride containing material that may be suitable for the high hermiticity dielectric cap 200. The present disclosure is not limited to only silicon nitride for the composition of the high hermiticity dielectric cap 200. In order to obstruct oxygen from reaching the metal gate conductor 102, the high hermiticity dielectric cap 200 is composed of a high-density dielectric. For example, to obstruct oxygen diffusion, the density of the material for the high hermiticity dielectric cap 200 is selected to be greater than 2.5 g/cm³. In some examples, the density of the material for the high hermiticity dielectric cap 200 ranges from 2.5 g/cm³ to 3.25 g/cm³. Dielectric materials having densities within the aforementioned ranges may provide compositions for some embodiments of the nitride containing material layer 199 for the high hermiticity dielectric cap 200. In some embodiments, the high hermicity dielectric cap 200 may have a density of approximately 3.17 g/cm³. In one example, the density of a nitride containing material layer 199 composed of silicon nitride is equal to 2.75 g/cm³. The nitride containing material layer 199 may have a thickness ranging from 1 nm to 5 nm.

FIGS. 19A and 19B illustrate planarizing the nitride containing material layer 199 to remove the portions of the layer that extend onto the upper surfaces of the first ILD 96 and the first contacts 114, wherein the portion of the nitride containing material layer 199 that remains provides the high hermiticity dielectric cap 200. For example, when viewed from the side cross-sectional view depicted in FIG. 19B, the outside sidewalls of the high hermiticity dielectric cap 200 are aligned to the outside sidewalls of the metal gate conductor 102. Further, following planarization, the upper surfaces of the high hermiticity dielectric cap 200 are coplanar with the upper surfaces of the first contacts 114 and the first ILD 96. The planarization process may be provided by chemical mechanical planarization (CMP).

FIGS. 19A and 19B also illustrate forming the middle contact etch stop layer (MCESL) 250 of low-k dielectric material atop the upper surfaces of at least the first ILD 96 and the high hermiticity dielectric cap 200. In some embodiments, the low-k dielectric material for the middle contact etch stop layer (MCESL) 250 is composed of silicon oxycarbide (SiOC). The dielectric constant of silicon oxycarbide (SiOC) may range between 2 and 3. However, silicon oxycarbide (SiOC) is only one example of a low-k dielectric material for use as the middle contact etch stop layer (MCESL) 250. Other low-k material are equally applicable. For example, a material is considered low-k when its k-value or dielectric constant at room temperature (e.g., 20 °C to 25°) is similar to or less than the k-value of SiO2, which is generally accepted to be about 3.9. However, for contact etch stop layer applications that typically includes silicon nitride, materials with k-values lower than silicon nitride may be considered as suitable materials for the low-k material middle contact etch stop layer (MCESL) 250. The k-value of silicon nitride is about 7.0. In some embodiments, the low-k material can be a dielectric material having a dielectric constant in the range from about 4 to about 6. Examples of the low-k materials within this range include but is not limited to SiBCN, SiOCN, and the like. In some embodiments, the low-k material for the middle contact etch stop layer (MCESL) 250 can be a dielectric material having a dielectric constant in the range from about 2 to about 6. Examples of low-k materials within this range can include but is not limited to, SiOC, SiCOH, and the like. The density of the middle contact etch stop layer (MCESL) 250 may range from 1.5 g/cm³ to 2.2 g/cm³.

In some embodiments, the low-k middle contact etch stop layer (MCESL) 250 may be deposited using a chemical vapor deposition (CVD) process, such as plasma enhanced chemical vapor deposition (PECVD), and/or metal organic chemical vapor deposition (MOCVD). In some embodiments, the low-k middle contact etch stop layer (MCESL) 250 may be deposited using atomic layer deposition (ALD). The thickness of the low-k middle contact etch stop layer (MCESL) 250 may range from 2 nm to 5 nm.

FIGS. 19A and 19B also illustrate forming a second interlevel dielectric layer (ILD) 106 atop the low-k middle contact etch stop layer (MCESL) 250. The second ILD 106 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. During the formation of the second ILD 106, the high hermiticity dielectric cap 200 composed of high density nitride containing material, such as silicon nitride, obstructs oxygen from reaching the metal gate conductor 102.

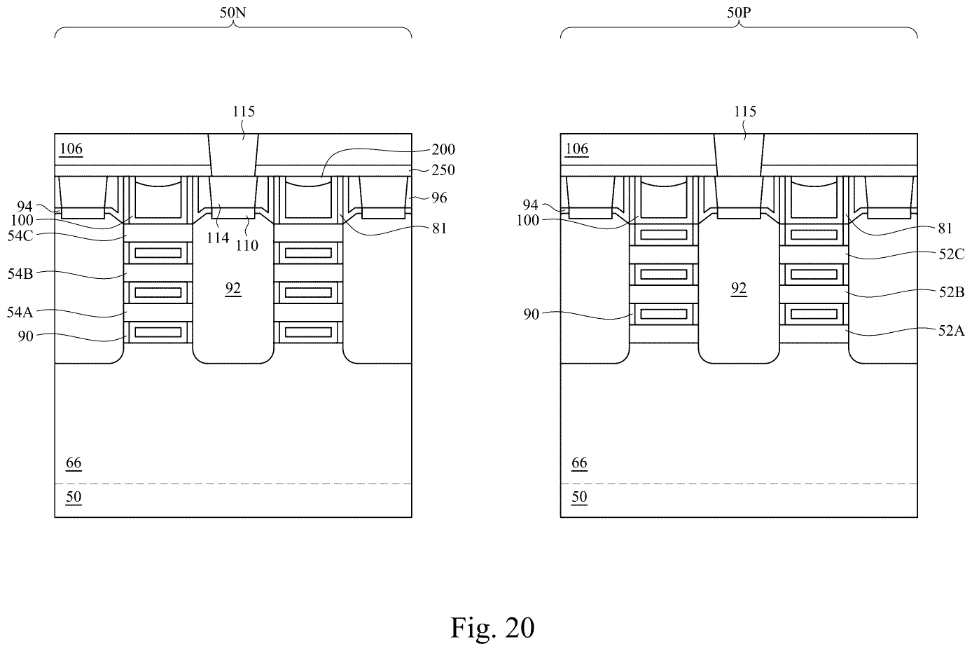

FIG. 20 illustrates forming second contacts 115 through the second ILD 106 to the first contacts 114 that are in electrical communication with the epitaxial source/drain regions 92. In some embodiments, the second ILD 106, and the low-k middle contact etch stop layer (MCESL) 250 are etched to form fourth recesses exposing surfaces of the first contact 114 to the epitaxial source/drain regions 92. The fourth recesses may be formed by etching using an anisotropic etching process, such as RIE, NBE, or the like. In some embodiments, the fourth recesses may be etched through the second ILD 106 using a first etching process; and may then be etched through the low-k middle contact etch stop layer (MCESL) 250 using a second etching process.

In FIG. 20, the second contacts 115 (may also be referred to as contact plugs) are formed in the fourth recesses. The second contacts 115 may each comprise one or more layers, such as barrier layers, diffusion layers, and fill materials. For example, in some embodiments, the second contacts 115 each include a barrier layer and a conductive material, and is electrically coupled to the underlying first contacts 114. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106. Although not depicted in FIG. 20, metal lines may be formed atop the second ILD 106 that are in electrical communication with the second contacts 115.

In the embodiment depicted with reference to FIGS. 18-20, the low-k middle contact etch stop layer (MCESL) 250 and the high hermiticity dielectric cap 200 are applied to both the devices in the p-type region 50P and the devices in the n-type region 50N. However, embodiments have been contemplated, in which the low-k middle contact etch stop layer (MCESL) 250 and the high hermiticity dielectric cap 200 may be formed in only one of the p-type region 50P and the n-type region 50N. For example, a mask, such as a photoresist, may be formed over the n-type region 50N, while exposing the p-type region 50P, and at least one of the low-k middle contact etch stop layer (MCESL) 250 and the high hermiticity dielectric cap 200 may be formed into the exposed p-type region 50P. In this example, the low-k middle contact etch stop layer (MCESL) 250 and the high hermiticity dielectric cap 200 are only formed in the p-type region. The mask may then be removed, and separate processing may then be applied to the n-type region.

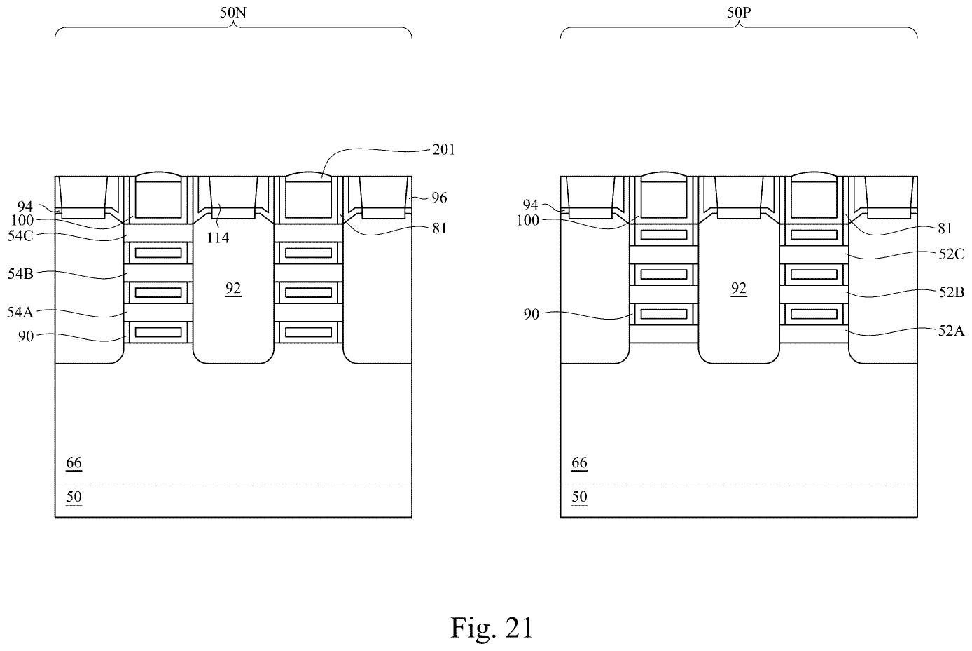

FIGS. 21-23 illustrate forming a high hermiticity metal cap 201 composed of a metal containing material, such as tungsten containing material, atop the metal gate conductor 102 and then forming a middle contact etch stop layer (MCESL) 250 of a low-k dielectric material on the high hermiticity metal cap 201. FIG. 21 illustrates forming the high hermiticity metal cap 201 directly on the upper surface of the metal gate conductor 102. In some embodiments, the density of the high hermicity metal cap 201 may be greater than 15 g/cm³. In some embodiments, the composition of the high hermiticity metal cap 201 may be composed of tungsten (W). In one example, a high hermicity metal cap 201 composed of tungsten may have a density of 19.254 g/cm³. In some embodiments, the high hermiticity metal cap 201 is formed using a selective deposition process. For example, chemical vapor deposition (CVD) or atomic layer deposition (ALD) may be employed using precursor gasses that provide that tungsten (W) is formed on the upper surface of the metal gate conductor 102, but is not substantially formed on the upper surface of the first ILD 96. For example, the precursor gases for forming the high hermiticity metal cap 201 may include at least one of tungsten hexachloride (WCl₆) and tungsten hexafluoride (WF₆). For example, tungsten hexafluoride (WF₆), which selectively adsorbs onto metal surfaces, allows for deposition of tungsten primarily on the desired metal areas, while minimizing deposition on other materials like oxides or insulators. In some embodiments, the tungsten containing precursor may be employed in combination with hydrogen gas. For example, hydrogen gas may be used in the process to facilitate the reduction of WF₆ to metallic tungsten on the metal surface. In some embodiments, the thickness of the high hermiticity metal cap 201 may range from 1 nm to 5 nm. In some embodiments, the high hermiticity metal cap 201 is formed on the upper surface of the metal gate conductor 102 before the first contacts 114 are formed to the epitaxial source/drain regions 92. The first contacts 114 may be formed after the high hermiticity metal cap 201 using methods that have been described above with reference to FIGS. 17A and 17B.

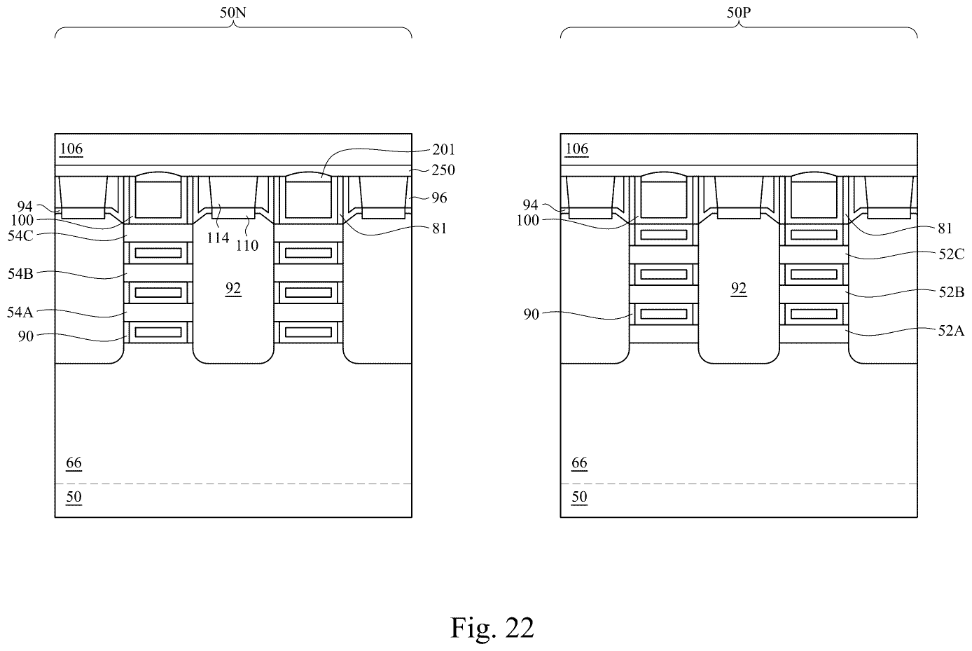

FIG. 22 illustrates an embodiment of forming a low-k middle contact etch stop layer (MCESL) 250 on the upper surfaces of at least the first ILD 96 and the high hermiticity metal cap 201. In some embodiments, the low-k middle contact etch stop layer (MCESL) 250 may be composed of silicon oxycarbide (SiOC), and may be deposited using a chemical vapor deposition (CVD) process, such as plasma enhanced chemical vapor deposition (PECVD) and/or metal organic chemical vapor deposition (MOCVD). The thickness of the low-k middle contact etch stop layer (MCESL) 250 may range from 2 nm to 5 nm. Further, details of the low-k middle contact etch stop layer (MCESL) 250 and its method of formation have been provided above with reference to FIGS. 19A and 19B. FIG. 22 also illustrates forming a second interlevel dielectric layer (ILD) 106 atop the low-k middle contact etch stop layer (MCESL) 250. Further, details of the second ILD 106 and its method of formation have been provided above with reference to FIGS. 19A and 19B. During the formation of the second ILD 106, the high hermiticity metal cap 201 composed of tungsten, obstructs oxygen from reaching the metal gate conductor 102.

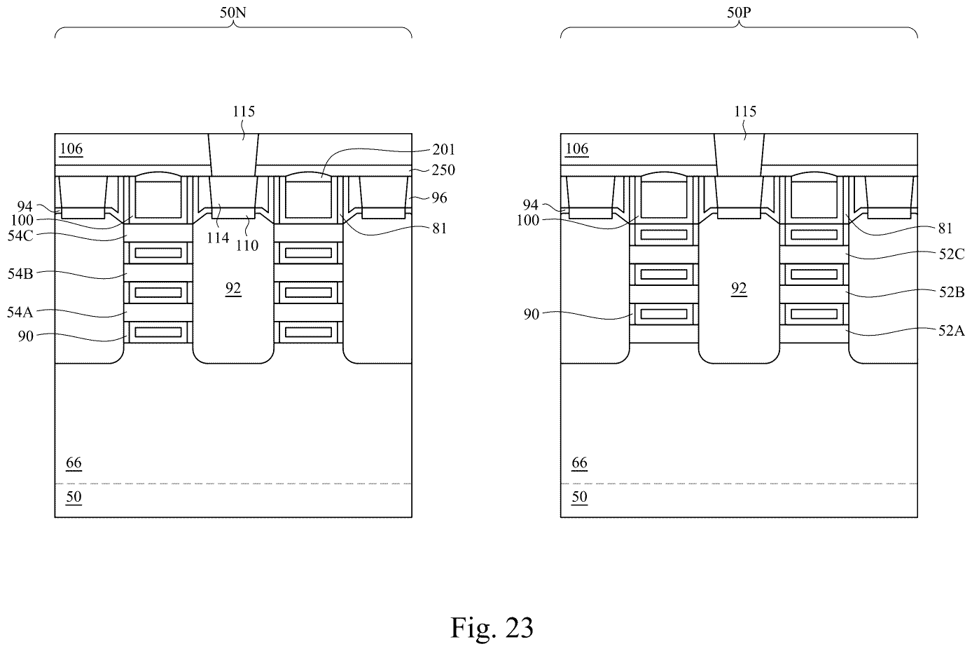

FIG. 23 illustrates forming second contacts 115 through the second ILD 106 to the first contacts 114 that are in electrical communication with the epitaxial source/drain regions 92. In some embodiments, the second ILD 106, and the low-k middle contact etch stop layer (MCESL) 250 are etched to form fourth recesses exposing surfaces of the first contact 114 to the epitaxial source/drain regions 92. The second contacts 115 may be formed in the fourth recess, and the second contacts 115 may each comprise one or more layers, such as barrier layers, diffusion layers, and fill materials (such as metal fill materials). A metal line (not shown) may be formed in electrical communication with the second contact 115.

In the embodiment depicted with reference to FIGS. 21-23, the low-k middle contact etch stop layer (MCESL) 250 and the high hermiticity metal cap 201 are applied to both the devices in the p-type region 50P and the devices in the n-type region 50N. However, embodiments have been contemplated, in which the low-k middle contact etch stop layer (MCESL) 250 and the high hermiticity metal cap 201 may be formed in only one of the p-type region 50P and the n-type region 50N. This may be accomplished through the use of block masks, e.g., photoresist masks, which allow for independent processing of the p-type region 50P and the n-type region 50N.

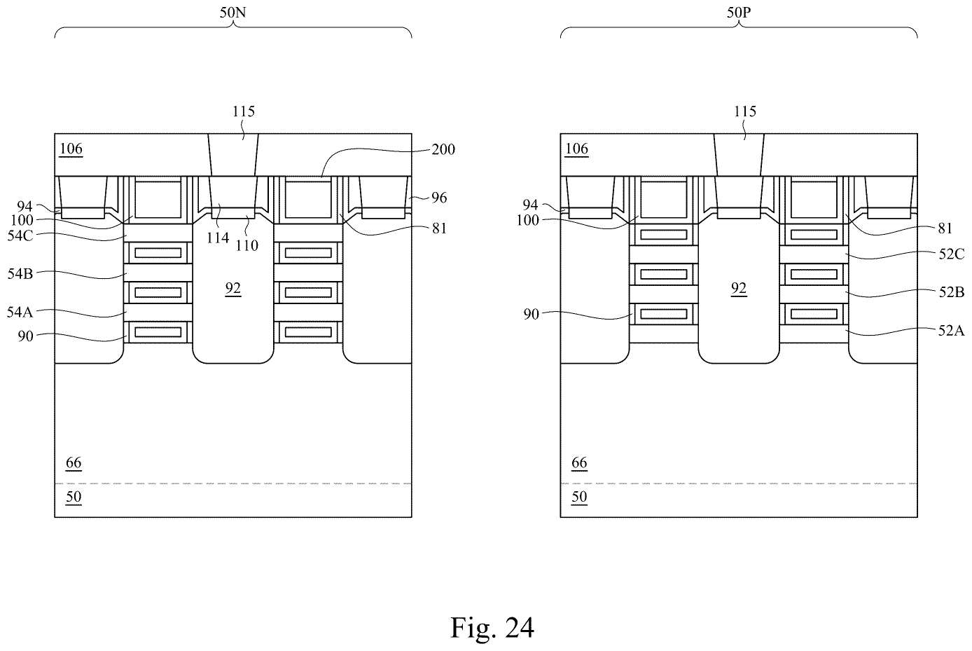

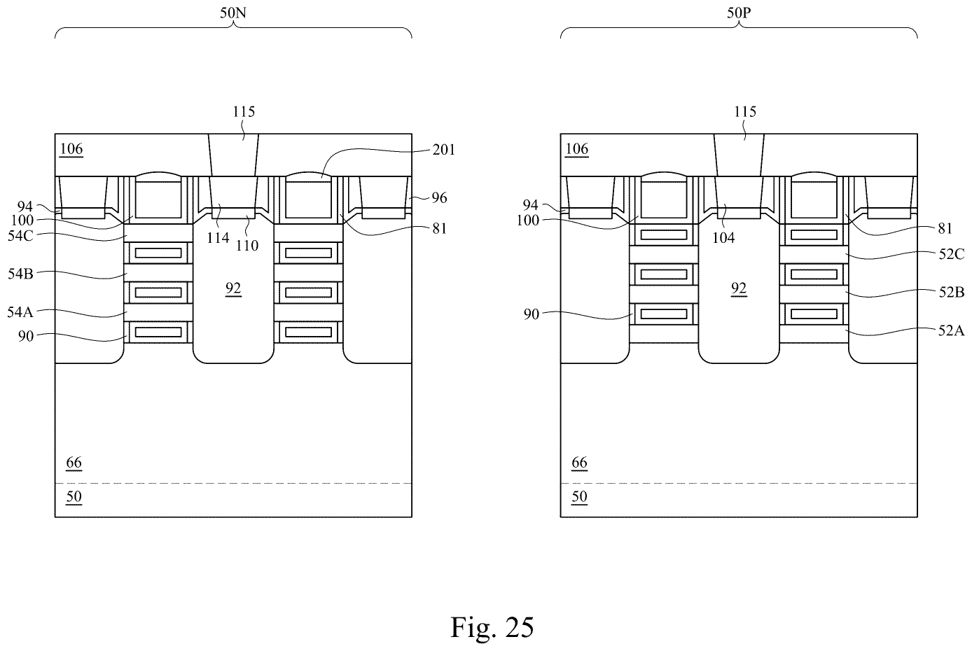

FIGS. 24 and 25 illustrate some embodiments of the present disclosure in which the low-k middle contact etch stop layer (MCESL) 250 is omitted. In the embodiment illustrated in FIG. 24, the second ILD 106 is composed of a low-k dielectric material that is formed directly on the upper surface of the first ILD 96 and directly on the upper surface of the high hermiticity dielectric cap 200. The low-k dielectric material of the second ILD 106 may have a dielectric constant at room temperature (e.g., 20 °C to 25°) that is similar to or less than the k-value of SiO 2, which is generally accepted to be about 3.9. Examples of low-k materials for the second ILD 106 include but is not limited to SiOC, SiCOH, and the like. In some embodiments, the dielectric constant may be less than 3.9. For example, the dielectric constant for the second ILD 106 may range from 2.0 to 3.75. For example, the dielectric constant of SiOC may range from 2.0 to 3.75. The density of SiOC may range from 1.5 g/cm³ to 2.2 g/cm³. For example, the dielectric constant of SiCOH may range from 2.0 to 3.2. The density of SiCOH can be approximately 2.15 g/cm³. The low-k material for the second ILD 106 may be deposited using chemical vapor deposition. In other embodiments, the low-k interlevel dielectric compositions for the second ILD 106 may include porous materials like carbon-doped silicon dioxide (CDO), porous organosilicate glass (OSG), or spin-on organic polymers. The low-k composition of the second ILD 106 may contribute to reducing the effective capacitance (Ceff) of the semiconductor device. During the formation of the second ILD 106, the high hermiticity dielectric cap 200 composed of a high-density nitride containing material, such as silicon nitride, obstructs oxygen from reaching the metal gate conductor 102. Further details on the composition of the high hermiticity dielectric cap 200, and its method of formation are described above with reference to FIGS. 18-19B.

In the embodiment illustrated in FIG. 25, the second ILD 106 is composed of a low-k dielectric material that is formed directly on the upper surface of the first ILD 96 and directly on the upper surface of the high hermiticity metal cap 201. The low-k dielectric material of the second ILD 106 and its method of formation have been described with reference to FIG. 24. During the formation of the second ILD 106, the high hermiticity metal cap 201 composed of tungsten obstructs oxygen from reaching the metal gate conductor 102. Further details on the composition of the high hermiticity metal cap 201, and its method of formation are described above with reference to FIG. 21.

Embodiments may achieve advantages. For example, a middle contact etch stop layer (MCESL) 250 composed of a low-k dielectric material is used to reduce the effective capacitance (Ceff) of the field effect transistor structure. In some embodiments, the methods and structures of the present disclosure position a high hermiticity material between the low-k dielectric material of the middle contact etch stop layer (MCESL) 250 and the metal gate conductor 102. The high hermiticity material may seal the upper surface of the metal gate conductor 102, and obstruct oxygen from reaching the metal gate conductor 102, substantially eliminating work function changes to the metal gate conductor 102 that could result in a shift of the threshold voltage for the semiconductor devices.

In an embodiment, a method comprising forming a gate cap on a metal gate conductor of a semiconductor device, the metal gate conductor being over a gate dielectric layer of a gate structure, wherein the gate cap has a first density; forming a first dielectric layer over the gate cap, the first dielectric layer having a second density, wherein the second density is less than the first density; forming an interlevel dielectric layer 106 over the first dielectric layer; and forming a contact through the interlevel dielectric layer and the first dielectric layer, wherein the contact is in electrical communication with a source/drain region 92 of the semiconductor device. In an embodiment, the first dielectric layer is silicon oxycarbide. In an embodiment, the first dielectric layer has a dielectric constant ranging from 2.0 to 4.5. In an embodiment, the forming of the gate cap comprises forming a recess in an upper surface of the metal gate conductor; depositing a dielectric material layer at least filling the recess; planarizing the dielectric material layer, wherein a remaining portion of the dielectric material layer in the recess provides the gate cap. In an embodiment, the gate cap comprises silicon nitride. In an embodiment, the first density of the gate cap ranges from 2.5 g/cm³ to 3.25 g/cm³. In an embodiment, the gate cap obstructs oxygen from processing for forming the interlevel dielectric layer from reaching the metal gate conductor.

In an embodiment, a method comprising: forming a gate structure including a metal gate conductor and a gate dielectric layer, wherein source/drain regions are on opposing sides of the gate structure; recessing an upper surface of the metal gate conductor relative to the gate dielectric layer; forming a metal cap on a recessed surface of the metal gate conductor of a semiconductor device; forming a first dielectric layer over the dielectric cap; forming an interlevel dielectric layer over the first dielectric layer; and forming contacts through the interlevel dielectric layer and the first dielectric layer, wherein the contacts are in electrical communication with the source/drain regions of the semiconductor device. In an embodiment, the first dielectric layer is silicon oxycarbide. In an embodiment, the first dielectric layer has a dielectric constant ranging from 2.0 to 4.5. In an embodiment, the dielectric cap comprises tungsten (W). In an embodiment, forming the dielectric cap comprises selective deposition of tungsten using chemical vapor deposition with a tungsten hexafluoride precursor. In an embodiment, forming the dielectric cap comprises selective deposition of tungsten using chemical vapor deposition with a tungsten hexachloride precursor. In an embodiment, the dielectric cap obstructs oxygen from processing for forming the interlevel dielectric layer from reaching the metal gate conductor.

In an embodiment, a device comprising: a gate structure including a metal gate conductor and a gate dielectric, the gate structure present on a channel region of a semiconductor material; source and drain regions on opposing sides of the channel region of the semiconductor material; a gate cap on the metal gate conductor, wherein the gate cap has a first density; a first dielectric layer over the gate cap, wherein the first dielectric layer has a second density, wherein the first density is greater than the second density; an interlevel dielectric layer 106 over the first dielectric layer; and a contact through the interlevel dielectric layer 106 and the first dielectric layer, wherein the contact is in electrical communication with the_source/drain region of the semiconductor device. In an embodiment, the gate dielectric has a U-shaped geometry when viewed from a side cross-section, and an upper surface of the metal gate conductor is recessed relative to the upper surface of the gate dielectric. In an embodiment, the first density of the gate cap ranges from 2.5 g/cm³ to 3.25 g/cm³. In an embodiment, the gate cap is comprised of silicon nitride. In an embodiment, the dielectric layer is comprised of silicon oxycarbide. In an embodiment, the gate cap is comprised of tungsten.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
forming a gate cap on a metal gate conductor of a semiconductor device, the metal gate conductor being over a gate dielectric layer of a gate structure, wherein the gate cap has a first density;
forming a first dielectric layer over the gate cap, the first dielectric layer having a second density, wherein the second density is less than the first density;
forming an interlevel dielectric layer over the first dielectric layer; and
forming a contact through the interlevel dielectric layer and the first dielectric layer, wherein the contact is in electrical communication with a source/drain region of the semiconductor device.

2. The method of claim 1, wherein the first dielectric layer is silicon oxycarbide.

3. The method of claim 1, wherein the first dielectric layer has a dielectric constant ranging from 2.0 to 4.5.

4. The method of claim 1, wherein the forming of the gate cap comprises:
forming a recess in an upper surface of the metal gate conductor;
depositing a dielectric material layer at least filling the recess; and
planarizing the dielectric material layer, wherein a remaining portion of the dielectric material layer in the recess provides the gate cap.

5. The method of claim 1, wherein the gate cap comprises silicon nitride.

6. The method of claim 1, wherein the first density of the gate cap ranges from 2.5 g/cm³ to 3.25 g/cm³.

7. The method of claim 1, wherein the gate cap obstructs oxygen from processing for forming the interlevel dielectric layer from reaching the metal gate conductor.

8. A method comprising:
forming a gate structure including a metal gate conductor and a gate dielectric layer, wherein source/drain regions are on opposing sides of the gate structure;
recessing an upper surface of the metal gate conductor relative to the gate dielectric layer;
forming a metal cap on a recessed surface of the metal gate conductor of a semiconductor device;
forming a first dielectric layer over the metal cap;
forming an interlevel dielectric layer over the first dielectric layer; and
forming contacts through the interlevel dielectric layer and the first dielectric layer, wherein the contacts are in electrical communication with the source/drain regions of the semiconductor device.

9. The method of claim 8, wherein the first dielectric layer is silicon oxycarbide.

10. The method of claim 8, wherein the first dielectric layer has a dielectric constant ranging from 2.0 to 4.5.

11. The method of claim 8, wherein the metal cap comprises tungsten (W).

12. The method of claim 8, wherein forming the metal cap comprises selective deposition of tungsten using chemical vapor deposition with a tungsten hexafluoride precursor.

13. The method of claim 8, wherein forming the metal cap comprises selective deposition of tungsten using chemical vapor deposition with a tungsten hexachloride precursor.

14. The method of claim 8, wherein the metal cap obstructs oxygen from processing for forming the interlevel dielectric layer from reaching the metal gate conductor.

15. A device comprising:
a gate structure including a metal gate conductor and a gate dielectric, the gate structure present on a channel region of a semiconductor material;
source/drain regions on opposing sides of the channel region of the semiconductor material;
a gate cap on the metal gate conductor, wherein the gate cap has a first density;
a first dielectric layer over the gate cap, wherein the first dielectric layer has a second density, wherein the first density is greater than the second density;
an interlevel dielectric layer over the first dielectric layer; and
a contact through the interlevel dielectric layer and the first dielectric layer, wherein the contact is in electrical communication with the source/drain regions of the device.

16. The device of claim 15, wherein the gate dielectric has a U-shaped geometry when viewed from a side cross-section, and an upper surface of the metal gate conductor is recessed relative to the upper surface of the gate dielectric.

17. The device of claim 16, wherein the first density of the gate cap ranges from 2.5 g/cm³ to 3.25 g/cm³.

18. The device of claim 15, wherein the gate cap is comprised of silicon nitride.

19. The device of claim 15, wherein the first dielectric layer is comprised of silicon oxycarbide.

20. The device of claim 15, wherein the gate cap is comprised of tungsten.
